(19) United States
(12) Patent Application Publication
(10) Pub. No.: US 2021/0028320 A1
(43) Pub. Date: Jan. 28, 2021

(54) THIN-FILM SEMITRANSPARENT PHOTOVOLTAIC DEVICE

(71) Applicant: Garmin Switzerland GmbH, Schaffhausen (CH)

(72) Inventor: Mohamed Bouchoucha, Marseille (FR)

(21) Appl. No.: 16/948,981

(22) Filed: Oct. 8, 2020

Related U.S. Application Data
(63) Continuation of application No. PCT/IB2019/000296, filed on Apr. 10, 2019.

(30) Foreign Application Priority Data
Apr. 11, 2018 (FR) 18 00301

(51) Int. Cl. H01L 31/0224

(52) U.S. Cl. CPC H01L 31/022425; H01L 31/0468; H01L 31/022483

(57) ABSTRACT

A thin-film semitransparent photovoltaic device can include: a transparent substrate; a front electrode including a transparent and electrically conductive material, arranged on the transparent substrate; one or more photoactive layers referred to as absorbers; one back electrode including a stack of at least one metal conductive layer in contact with the absorber and of a metal barrier layer deposited uniformly over the whole of the metal conductive layer; a metal contact pickup layer; and a contact pickup region (10). The thickness of the metal barrier layer is greater than 5% of the thickness of the metal conductive layer and is greater than 5 nm.

### RELATED APPLICATIONS

The present application is a continuation of, and claims priority benefit to, co-pending international application entitled, “OPTIMISATION DU CONTACT ELECTRIQUE METAL/METAL DANS UN DISPOSITIF PHOTOVOLTAIQUE SEMI-TRANSPARENT EN COUCHES MINCES,” International Application No. PCT/IB2019/000296, filed Apr. 10, 2019, which claims priority to French Patent Application No. 18/00301, filed Apr. 11, 2018. Each of the above-referenced applications are hereby incorporated by reference into the current application in their entirety.

### BACKGROUND

A distinction is drawn in literature among various types of semiconductor materials used in photovoltaic devices, such as crystallized solid materials, organic materials (polymers or small molecules) or also inorganic thin films (amorphous or polycrystalline). In most cases, a metal film is used for collecting electrical charges generated by these devices under illumination. These metal films generally form an electrode, collection buses or interconnections among the different cells constituting the photovoltaic module.

### DRAWINGS

FIG. 1A is a cross-sectional view of a photovoltaic stack.

FIG. 1B is a plan view of the photovoltaic stack of FIG. 1A, within which transparency is achieved.

FIG. 1C is a plan view similar to FIG. 1B to which were added VIA-type contact regions.

FIG. 1D is a cross-sectional view according to direction X of FIG. 1C.

FIG. 1E is a cross-sectional view based on FIG. 1D to which was added the insulation layer.

FIG. 1F is a cross-sectional view based on FIG. 1E to which was added the metal contact layer.

FIG. 2 is a cross-sectional view of an optimized contact pickup region according to various embodiments of the invention.

### DETAILED DESCRIPTION

To improve the performance of photovoltaic modules, a person skilled in the art knows that increasing for example the thickness of the metal electrodes allows one to decrease losses due to the Joule effect. In this case, a metal A, which has been in open air (metal electrode of the initial cell), must be placed into contact with another conductor B to thicken said electrode, and thus increase its overall conductivity. However, certain metals, including aluminum (Al) and copper (Cu), currently used to form for example the metal electrode of thin-film photovoltaic devices, are subject to surface oxidation in open air or even in atmospheres whose oxygen rates are controlled. An oxide is formed that is commonly called native oxide. This fine layer of native oxide, which is a few nanometers thick, is usually electrically insulating. This is the case particularly for aluminum and copper oxides. In this case, the stack composed of the metal electrode A, its oxide and the conductor B do not exhibit an improved conductivity as hoped for due to the thickening afterward of the metal electrode because the electrical contact resistance between the two metals is very significant due to the presence of the native oxide between the two metals.

The same phenomenon is observed when one attempts to place several photovoltaic cells in series or in parallel afterward in order to control the voltage and current levels outputted at the photovoltaic modules. As before, it is necessary to optimize the conductivity of the metal A-native oxide-metal B stack to maximize the performance of said modules.

This same problem also appears in thin-film semitransparent photovoltaic devices. These photovoltaic devices are composed of:
Solid and opaque surfaces containing the stack of active photovoltaic layers,
Transparent surfaces formed of the transparent substrate and possibly transparent conductive or insulating materials.

For example, semitransparency may be achieved based on solid photovoltaic modules, in other words not having any transparency regions. In this case, the transparent regions are generally obtained by photolithographic etching processes by etching the layers of the photovoltaic stack to expose transparency regions to light. For example, in the case of amorphous silicon-based photovoltaic modules, the stack is composed in the following manner:
A substrate, for example glass;
A first transparent electrode, for example a zinc oxide doped with aluminum;
An active photovoltaic layer, for example an amorphous silicon-based junction;
A second metal electrode, for example aluminum.

After etching the different layers constituting the photovoltaic stack (the first electrode, the active photovoltaic layer and the second electrode), the metal-metal type of contact pickups are necessary to connect the electrically active regions to the collection buses and to connect the unit cells among each other (in series and/or in parallel) in order to obtain a photovoltaic module. The problem of the metal-metal contact pickup is intensified in the case of semitransparent photovoltaic devices because contact pickups are achieved on surfaces whose wider sides do not exceed a few tens of micrometers generating contact pickup surfaces measuring a few hundred square micrometers. Thus, if the metal electrode, as mentioned in the example above, is aluminum, the native oxide, in this case aluminum oxide, may have a thickness of 3 to 6 nm. The combination of this material with a contact surface hardly a few hundred square micrometers in size results in an unstable electrical contact having high electrical resistance and which results in a degradation of the electrical efficiency of the device.

One of the solutions to remedy this problem would be to modify the nature of the metal electrode. This solution is not attractive from an industrial perspective because aluminum is a preferred material in the realm of amorphous silicon-based photovoltaic modules for the following reasons:
low cost;
low resistivity;
compatibility with the material of the active photovoltaic layer, in this case amorphous silicon in particular;
the ability to sequence etching steps to produce semitransparency;
the availability of and control of manufacturers over deposition and etching processes.

Another solution consists of eliminating the aluminum oxide layer, which is formed on its surface prior to the deposition of the second metal allowing the contact pickup. It is possible to use for example plasma etching, and to deposit the second metal immediately after plasma etching, without having to break the vacuum conditions between the etching step and the metal deposition step. This step requires deposition equipment having a plasma module in the deposition chamber or in the adjacent chamber. This configuration may not be available in production equipment and in this case, the investment to upgrade it may be substantial.

Embodiments of the present invention provide a thin-film semitransparent photovoltaic device, whose metal-metal contact pickups are optimized in order to minimize the electrical resistances of metal-metal contact and to thereby increase the electrical performance of said photovoltaic device.

More specifically, embodiments of the present invention can:
(a) Minimize or even to eliminate the formation of the native oxide of aluminum by adding a barrier layer after the aluminum deposition;
(b) Allow one to obtain semitransparency by etching steps that are compatible with industrial constraints;
(c) Minimize the resistivity of the contact pickups, even when the contact pickup surfaces have very small dimensions, in the order of about one hundred square micrometers.

In the remainder of the document, a photovoltaic device refers to any type of photovoltaic cell or module. The photovoltaic modules are composed of a plurality of interconnected photovoltaic cells on the basis of a series, parallel, series-parallel or parallel-series architecture. A thin-film photovoltaic device refers to photovoltaic devices composed of a stack of thin layers having a thickness less than 20 μm (not including the substrate). A semitransparent photovoltaic device is composed of transparency regions and opaque active photovoltaic regions.

Embodiments of the present invention provide a thin-film semitransparent photovoltaic device comprising at least:
(a) A transparent substrate, for example glass or a polymer (having a thickness ranging from a few hundred μm to several mm);
(b) One front electrode composed of an electrically conductive and transparent material, for example a conductive transparent oxide such as ZnO:Al (zinc oxide doped with aluminum), and deposited on the transparent substrate;
(c) One or more photoactive layer(s), known as absorber(s), for example on the basis of amorphous silicon, organic layers, perovskite;
(d) One back electrode composed of a stack of at least:
   a. One metal conductive layer having a thickness E2 in contact with said absorber, for example aluminum, silver, copper;
   b. One metal barrier layer having a thickness E1, for example molybdenum, nickel, deposited uniformly over the entire said metal conductive layer;
(e) One metal contact pickup layer, for example aluminum, silver, copper;
(f) One contact pickup region of the back electrode/contact pickup metal layer-type, characterized in that the layer E1 of said metal barrier layer is greater than 5% of the thickness E2 of said metal conductive layer and is greater than 5 nm.

Metal-metal types of contacts between the back electrode and a metal contact layer are necessary in thin-film semitransparent photovoltaic devices. They enable the active photovoltaic regions to be electrically interconnected and the active photovoltaic regions to be connected to the collection buses.

According to the architecture selected to obtain semitransparency of the photovoltaic devices, the contact pickup surfaces may be several hundred square micrometers in size. In this case, they require an optimization of the electrical contact resistance. According to the invention, this optimization is achieved by means of the characteristics of the back electrode composed of a stack of at least:
(a) One metal conductive layer in contact with the absorber, for example aluminum, silver, copper;
(b) One metal barrier layer in contact with said metal conductive layer, for example molybdenum or nickel;

The metal conductive layer combined with the metal contact pickup layer enables the collection of electricity produced by the absorber and ensures its conduction up to the output points of the modules (generally a positive polarity stud and a negative polarity stud).

The metal barrier layer allows one to eliminate the appearance of a native oxide of said metal conductive layer, an oxide causing, particularly in the case of small contact surfaces, an increase of the resistivity of the contact, and thus a decrease in the electrical performance of the photovoltaic device.

However, choosing the metal conductive layer and the metal barrier layer is determined among other things by:
(a) the physical characteristics of the materials (conductivity, diffusion in the absorber, etc.);
(b) etching processes allowing one to achieve semitransparency within photovoltaic stacks, and particularly based on the etching of layers constituting the back electrode;
(c) the production costs.

The thin-film semitransparent photovoltaic devices according to the invention are characterized in that the thickness E1 of said metal barrier layer is greater than 5% of the thickness E2 of said metal conductive layer and is greater than 5 nm in order for the metal barrier layer to perform its function as an oxidation barrier and to not be over-etched when achieving semitransparency.

Advantageously, the thickness of the metal barrier layer is less than 100 nm in order to not increase the resistivity of all the conductive paths composed of the back electrode stack/metal contact pickup layer.

According to an advantageous embodiment, the metal barrier layer is a layer of molybdenum, nickel, silver, palladium, platinum, gold, chromium or tungsten.

According to an advantageous embodiment, the absorber is an amorphous silicon-based junction.

According to an embodiment, the metal conductive layer is a layer of aluminum, copper, silver or an aluminum-copper alloy.

Advantageously, for thin-film semitransparent amorphous silicon-based photovoltaic devices, the metal conductive layer is an aluminum layer having a thickness E2 ranging between 50 nm and 2,000 nm, and the metal barrier layer is a layer of molybdenum or nickel. For example, a conductive layer of aluminum having a thickness of 500 nm will be advantageously combined with a barrier layer of molybdenum having a thickness of 50 nm.

According to an embodiment of the device according to the invention, the metal-metal contact region has a surface of about one hundred square micrometers.

The invention will now be described in greater detail using the description of the drawings 1 to 2.

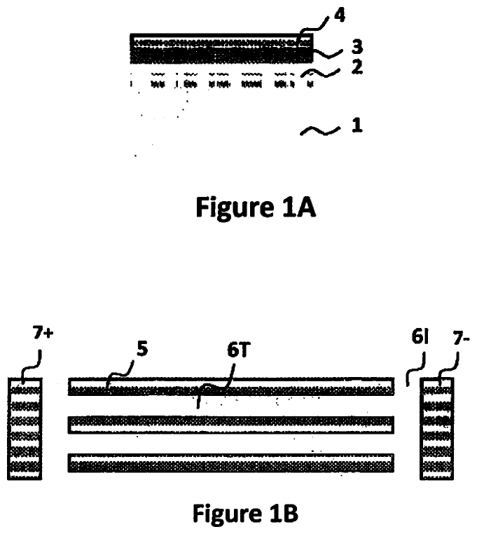

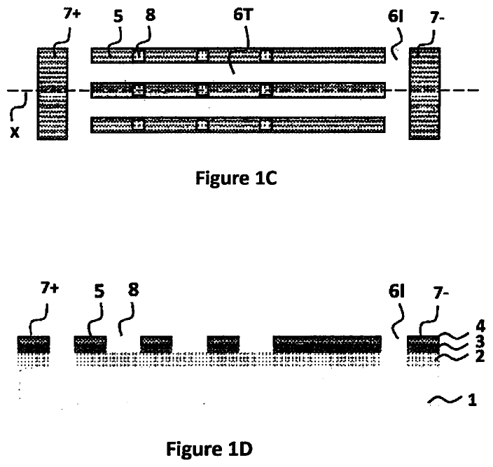

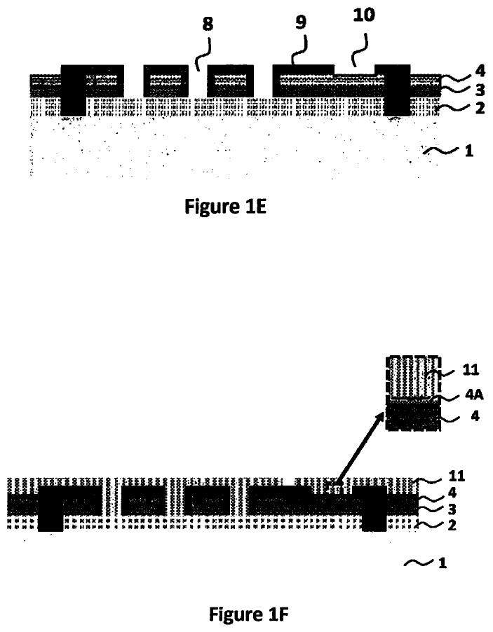

FIG. 1A is a cross-sectional view of a photovoltaic stack. In this example, the stack is composed of:
(a) a glass substrate (1);
(b) a front electrode (2), namely a transparent conductive oxide, for example zinc oxide (ZnO);
(c) an absorber layer (3) on the basis of amorphous silicon (a_Si);
(d) a back electrode (4) of metal.

By means of photolithography etching processes known to a person skilled in the art, it is possible to transform this stack to obtain a semitransparent photovoltaic cell. The first step of this process consists of creating transparency regions (6T) within the active regions and insulating the collection buses (7) by means of transparency regions (6I). The transparency regions (6T and 6I) are created by successive etchings of the back electrode (4), the absorber (3) and the front electrode (2).

FIG. 1B is a plan view of the preceding stack in which a band-like transparency and insulation of the collection bus were achieved. It represents a succession of opaque and transparent horizontal bands. The opaque horizontal bands form active photovoltaic regions (5). The vertical opaque bands form collection buses (7+ and 7−) that are electrically insulated from the active photovoltaic regions (5).

The transparency regions (6T) electrically insulate the photovoltaic bands that constitute insulated active photovoltaic regions (5) that form unit cells among each other. In order to electrically connect these insulated active photovoltaic regions among each other (in series and/or in parallel) and to the collection buses (7+ and 7−) to obtain a photovoltaic module, it is necessary to create an oxide-metal type of contact pickup. In the remainder of the document, the term “via” is used to designate the oxide-metal contact pickup described below. Creating a via-type contact comprises several consecutive steps. One shall consider the example of an architecture in semitransparent bands like the one in FIG. 1B. One proceeds as follows:

Step 1: In the active photovoltaic regions (5), there are etched contact pick-up (8) regions. In the example of FIG. 1C, these contact pickup regions (8) have a square shape and are perfectly enclosed inside active photovoltaic regions. The contact pickup regions (8) originate from etching the back electrode (4) and the absorber layer (3) by conventional photolithography processes known to a person skilled in the art. FIG. 1D is a cross-sectional view of FIG. 1C according to direction X, where the VIA-type contact pickup regions (8) appear.

Step 2: An electrical insulation layer (9) is inserted to electrically insulate the front electrode (2) from the back electrode (4). FIG. 1E is a cross-sectional view stemming from FIG. 1D to which was added the insulating layer (9). This electrical insulation layer is for example a transparent, permanent and photosensitive resin. The VIA-type contact pickup regions (8) are left empty to create a metal-oxide contact pickup whose objective is to improve the charge collection. The architecture of the photovoltaic module requires metal-metal contact pickup regions (10). The invention allows one to optimize this type of metal-metal contact pickup.

Step 3: A metal contact pickup layer (11) is then deposited and subsequently etched for example by means of another photolithography step in order to connect the two buses (7+ and 7−) respectively to the front electrode (2) and the back electrode (4) in order to make the semitransparent photovoltaic module functional as described in FIG. 1F.

However, in the known processes for achieving semitransparency such as described precedingly, the metal electrode, made of aluminum for example, is left out in the open air and a native oxide (4A), for example aluminum oxide commonly referred to as alumina, forms at its surface. This native oxide (4A) may have a thickness of several nanometers (3 to 6 nm with respect to alumina) and/or have a substantial insulating capacity due to its density (3.4 with respect to alumina) and its electrical permittivity (10.5 with respect to alumina). The electrical contact resistance which results may be elevated and drastically worsen the performance of the photovoltaic module.

The invention aims to optimize the metal-metal contact pickup composed of a metal electrode (4) and the contact pickup metal (11). The invention relates to a specific architecture of the metal electrode (4).

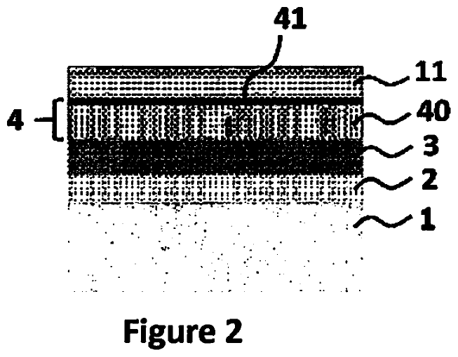

FIG. 2 is a cross-sectional view of an optimized contact pickup region according to the invention. The metal electrode (4) is composed of a metal conductive layer (40) and a metal barrier layer (41).

The metal conductive layer (40) could be aluminum, copper, silver, gold, platinum, or even a metal alloy. However, to maximize the performance of the semitransparent photovoltaic devices, the metal conductive layer (40) must be selected as a function of several criteria:
(a) Compatibility with the other materials of the photovoltaic cell; for example, copper cannot be used in such a device if the absorber is amorphous silicon-based since it diffuses in the material.
(b) Low electrical resistivity to minimize the electrical contact resistance.
(c) Low costs.
(d) Possibility of creating semitransparent photovoltaic devices according to industrial processes.

In light of the conditions, the metal conductive layer (40) will advantageously either be:
(a) Copper, in a copper-aluminum alloy for organic and perovskite semitransparent photovoltaic devices, or
(b) Aluminum for amorphous silicon-based, organic and perovskite semitransparent photovoltaic devices.

It shall be noted that the adopted solutions are oxidizable metal layers whose native oxide deteriorates the contact pickup between the metal electrode and the metal of the contact pickup. The thickness of the metal conductive layer shall be preferably between 50 nm and 2,000 nm.

The metal barrier layer (41) must also be selected as a function of several criteria, as follows:
(a) Oxidation of the barrier layer must be low, or even non-existent,
(b) Deposition of the metal barrier layer must be executable under vacuum immediately after deposition of the metal conductive layer (40),
(c) The nature of the material must be compatible with industrial processes regarding the semitransparency of photovoltaic devices.

Preferably molybdenum and nickel are used as a metal barrier layer (41) when the metal conductive layer is aluminum. The thickness of the barrier layer (41) must also be optimized:
(a) Its thickness must allow it to perform the barrier function with respect to the oxidation of aluminum; it must be completely uniform and have a minimum thickness of 5 nm. It shall be noted that since current industrial processes do not allow achieving sufficient uniformity, it is recommended that a 20 nm-thick metal barrier layer shall be used.
(b) Its thickness must be compatible with etching processes on the metal conductive layer. If the thickness is too small, over-etching of said barrier layer may occur and affect the performance of the contact pickup and thus the photovoltaic device.
   In order to meet all these criteria, the thickness E1 of the metal barrier layer (41) must be greater than 5% of the thickness E2 of the metal conductive layer (40).

Therefore, the advantage of the present architecture is that it enables the creation of high-performance electrical contacts having small dimensions (a few hundred square micrometers) on an oxidizable metal conductive layer without requiring the use of plasma etching if the implementation of this type of etching proves to be restrictive for cost- or equipment availability-related reasons.

### REFERENCES IN THE FIGURES

| | |
|---|---|
| 1 | Substrate |
| 2 | Front electrode |
| 3 | Absorber |
| 4 | Back electrode |
| 4A | Native oxide of the back electrode |
| 40 | Metal conductive layer |
| 41 | Metal barrier layer |
| 5 | Active photovoltaic regions |
| 6T | Transparency regions |
| 6I | Transparency regions of the insulation of the collection buses |
| 7+, 7− | Collection bus |
| 8 | Oxide-metal contact pickup regions |
| 9 | Electrical insulation layer |
| 10 | Metal-metal contact pickup regions |
| 11 | Metal contact pickup layer |

### WORKING EXAMPLE

An actual example of a semitransparent photovoltaic device was created. Its characteristics are as follows:
(a) the transparent substrate is glass; its thickness is 550 μm,
(b) the front electrode (2) is composed of a zinc oxide layer having a thickness of 1,000 n m,
(c) the absorber (3) is an amorphous silicon-based photoactive layer having a thickness of 350 nm,
(d) the back electrode (4) is composed of a stack of:
   a. an aluminum conductive layer (40) having a thickness of 500 nm, in contact with said absorber (3),
   b. a molybdenum barrier layer (41) having a thickness of 50 nm, in contact with said aluminum conductive layer.
(e) an electrical insulation layer (9) made of resin having a thickness of 2,000 nm,
(f) an aluminum contact pickup layer (11), having a thickness of 500 nm.

Etching of the back electrode (4) is achieved by means of a phosphoric acid solution, whose phosphoric acid concentration is 70%. At an ambient temperature, the difference in etching speed between aluminum and molybdenum is less than 20 nm per minute, molybdenum being the material that can be etched more quickly. Thus, by executing one single photolithographic masking step and one single chemical etching step, over-etching or lateral etching of the molybdenum layer with respect to the aluminum layer is less than 500 nm, which is acceptable for patterns that are several micrometers wide.

By way of example, the total electrical resistance of a photovoltaic device whose active region is 10 cm² may be divided by two by using a back electrode protected by a molybdenum layer as described in this working example.

1. A thin-film semitransparent photovoltaic device comprising:
a transparent substrate;
a front electrode including a transparent, electrically conductive material, arranged on the transparent substrate;
at least one photoactive absorber; and
a back electrode including—
a metal conductive layer in contact with the absorber;
a metal barrier layer deposited in a uniform manner over the entire metal conductive layer;
wherein the thickness of the metal barrier layer is greater than 5% of the thickness of the metal conductive layer and is greater than 5 nm.

2. The device of claim 1, wherein the metal barrier layer has a thickness less than 100 nm.

3. The device of claim 1, wherein the metal barrier layer includes a molybdenum, nickel, silver, palladium, platinum, gold, chromium or tungsten layer.

4. The device of claim 1, wherein the absorber includes an amorphous silicon-based junction.

5. The device of claim 1, wherein metal conductive layer includes an aluminum, copper, silver or aluminum/copper alloy.

6. The device of claim 1, wherein the metal conductive layer has a thickness ranging between 50 nm and 2,000 nm.

7. The device of claim 1, further including a metal-metal contact pickup region with a surface area of about one hundred square micrometers.
